(19) United States
(12) Patent Application Publication
(10) Pub. No.: US 2024/0304754 A1
(43) Pub. Date: Sep. 12, 2024

(54) ELECTRON OVERFLOW OF AIGaN DEEP ULTRAVIOLET LIGHT EMITTING DIODES

(71) Applicant: THE REGENTS OF THE UNIVERSITY OF MICHIGAN, Ann Arbor, MI (US)

(72) Inventors: Ayush PANDEY, Ann Arbor, MI (US); Zetian MI, Ann Arbor, MI (US)

(21) Appl. No.: 18/569,162

(22) PCT Filed: Jun. 13, 2022
(86) PCT No.: PCT/US2022/033251

§ 371 Date: Dec. 11, 2023

Related U.S. Application Data
(60) Provisional application No. 63/209,898, filed on Jun. 11, 2021.

(51) Int. Cl. H01L 33/14; A61L 2/10; A61L 2/26; A61L 9/20; B82Y 20/00; C02F 1/32; H01L 33/06; H01L 33/32

(52) U.S. Cl. CPC H01L 33/145; A61L 2/10; A61L 2/26; A61L 9/20; C02F 1/325; H01L 33/06; H01L 33/325; A61L 2202/11; A61L 2209/12; B82Y 20/00; C02F 2201/3222; C02F 2303/04

(57) ABSTRACT

Various embodiments are based on the study of the design, epitaxy, and performance characteristics of deep ultraviolet (UV) AlGaN light emitting diodes (LEDs). By combining tunnel junction and polarization-engineered AlGaN electron blocking layer, a maximum external quantum efficiency and wall-plug efficiency of 0.35% and 0.21%, respectively, were measured for devices operating at approximately 245 nanometers (nm), which are over one order of magnitude higher than previously reported tunnel junction devices at this wavelength. Severe efficiency droop, however, was measured at very low current densities (approximately 0.25 A/cm2), which, together with the transverse magnetic (TM) polarized emission, are identified to be the primary limiting factors for the device performance. Detailed electrical and optical analysis further show that the observed efficiency droop is largely due to an electrical effect, instead of an optical phenomenon. Studies based on various embodiments suggest that AlGaN deep UV LEDs with efficiency comparable to InGaN blue-emitting quantum wells can be potentially achieved, if issues related to electron overflow and TM polarized emission are effectively addressed.

### CROSS-REFERENCE TO RELATED APPLICATIONS

This is a U.S. conversion of PCT Patent Application No. PCT/US2022/033251 filed Jun. 13, 2022, which claims the priority to U.S. Provisional Patent Application No. 63/209,898 filed Jun. 11, 2021, both of which are incorporated herein in their entirety.

### BACKGROUND OF THE INVENTION

Ultraviolet (UV)-C semiconductor light emitting diodes (LEDs) are gaining much attention due to their ability to inactivate pathogens, which is essential for water purification, food preservation, and surface sterilization. Their ease of use, small size, and low power requirements, compared to conventional mercury and xenon lamps, will enable much broader and widespread application in combating, or even possibly preventing another global pandemic. While conventional UV-C devices have been focused on 260-270 nanometer (nm) wavelength range, recent studies suggested that even shorter wavelengths, e.g., approximately 200-220 nm in the far UV-C, are not only more effective at sterilization but can significantly limit the dangers of human exposure to UV radiation due to the shorter penetration depth of higher energy photons in skin. To date, however, such devices exhibit extremely low efficiency, due to the low internal quantum efficiency (IQE), insufficient light extraction, and the difficulty in p-doping of ultrawide bandgap aluminum gallium nitride (AlGaN) materials. In this regard, tunnel junction-based devices have garnered significant attention, offering a route that can alleviate some of the critical issues associated with the low hole injection by providing a conductive, transparent n-doped layer for enhanced charge carrier (hole) injection, current spreading, and light extraction. Large electric fields within the tunnel junction layer can be created through polarization engineering, enabling relatively narrow depletion widths despite the wide bandgap AlGaN materials. To realize UV-C LEDs emitting below 250 nm, however, the Al composition of AlGaN needs to be tuned >75%, which causes serious issues for p-type as well as n-type doping. These factors not only drastically reduce the probability of the inter-band tunneling of charge carriers across the tunnel junction but also lead to extremely poor charge carrier (particularly hole) injection. Consequently, the best reported EQE values is well below 0.1% for AlGaN tunnel junction LEDs operating below 250 nm.

Recently, significant advances have been made in the molecular beam epitaxy (MBE) of AlGaN and their device applications. With the use of MBE, relatively efficient p-type conduction of Al-rich AlGaN has been achieved through in situ surface Fermi level control under slightly Ga-rich epitaxy conditions. This growth process also leads to the formation of Ga-rich clusters in AlGaN layers, which provide highly localized sites for efficient radiative recombination, thereby overcoming the efficiency limitation placed by dislocations. To date, however, there are few studies of tunnel junction AlGaN deep UV LEDs towards far UV-C emission. Moreover, the currently reported tunnel junction AlGaN deep UV LEDs generally display a pronounced efficiency droop, even for operation at very low current densities, which limits their high-power applications. Efficiency droop is a well-studied phenomenon in InGaN-based optoelectronic devices, with the underlying causes including Auger recombination, electron overflow, defect-related mechanisms, carrier delocalization, and a combination of these factors. To date, however, the underlying cause for the severe efficiency droop of AlGaN deep UV LEDs has remained largely unexplored.

### SUMMARY OF THE INVENTION

Various embodiments in accordance with the present disclosure can address the disadvantages described above.

Various embodiment in accordance with the present disclosure are based on a detailed study of the design, epitaxy, and performance characteristics of AlGaN tunnel junction deep UV LEDs. In various embodiments, by incorporating a magnesium (Mg) doped, polarization engineered electron blocking layer, a maximum external quantum efficiency (EQE) and wall-plug efficiency (WPE) of 0.35% and 0.21%, respectively, were measured for devices operating at approximately 245 nm, which are over one order of magnitude higher than previously reported tunnel junction devices at this wavelength. Severe efficiency droop, however, was measured at very low current densities (approximately 0.25 A/cm²), which, together with the transverse magnetic (TM) polarized emission, are identified to be the primary limiting factors for the performance of AlGaN deep UV LEDs. Detailed electrical and optical analysis further suggests that the observed efficiency droop is largely due to an electrical effect, instead of an optical phenomenon. Various embodiments in accordance with the present disclosure provide new insights on how to further improve the efficiency of UV-C and far UV-C LEDs that are relevant for a broad range of applications including water and air purification and sterilization.

In various embodiments, the present disclosure includes a light emitting diode (LED) including a composition graded electron blocking layer. It is noted that the LED is operable for emitting light.

In various embodiments, the composition graded electron blocking layer includes aluminum gallium nitride (AlGaN).

In various embodiments, the composition graded electron blocking layer includes magnesium (Mg) doping.

In various embodiments, the composition graded electron blocking layer includes Mg doped AlGaN.

In various embodiments, the composition graded electron blocking layer includes an aluminum (Al) composition graded from approximately 95% to approximately 75%.

In various embodiments, the composition graded electron blocking layer is polarization engineered.

In various embodiments, the light includes a peak in the electroluminescence (EL) spectrum less than 250 nanometers (nm).

In various embodiments, the LED includes an external quantum efficiency (EQE) of at least 0.3% at a current density of at least 0.25 A/cm².

In various embodiments, the LED includes a wall-plug efficiency (WPE) of at least 0.2% at a current density of at least 0.25 A/cm².

In various embodiments, the LED includes a nearly invariant carrier lifetime over an excitation range of 0.1 to 3000 W/cm².

In various embodiments, the present disclosure includes a light emitting diode (LED) heterostructure, including a quantum well layer, an electron blocking layer, and a tunnel junction. Note that the LED heterostructure is operable for emitting light.

In various embodiments, the electron blocking layer includes composition grading.

In various embodiments, the electron blocking layer includes aluminum gallium nitride (AlGaN).

In various embodiments, the electron blocking layer includes magnesium (Mg) doping.

In various embodiments, the electron blocking layer includes Mg doped AlGaN.

In various embodiments, the electron blocking layer includes an aluminum (Al) composition graded from approximately 95% to approximately 75%.

In various embodiments, the light includes a peak in the electroluminescence (EL) spectrum less than 250 nanometers (nm).

In various embodiments, the tunnel junction includes a gallium nitride (GaN) layer.

In various embodiments, the present disclosure includes a light emitting diode (LED) including a electron blocking layer and a tunnel junction layer. It is noted that the LED is operable for emitting light at a peak in the electroluminescence (EL) spectrum less than 250 nm.

In various embodiments, the light includes a peak in the EL spectrum in a wavelength range of approximately 210-259 nm.

In various embodiments, the electron blocking layer includes magnesium (Mg) doping.

In various embodiments, the electron blocking layer includes composition grading.

In various embodiments, the electron blocking layer is polarization engineered.

In various embodiments, the electron blocking layer includes AlGaN.

In various embodiments, the LED includes an external quantum efficiency (EQE) of at least 0.3% at a current density of at least 0.25 A/cm².

In various embodiments, the LED includes a wall-plug efficiency (WPE) of at least 0.2% at a current density of at least 0.25 A/cm².

While various embodiments in accordance with the present disclosure have been specifically described within this Summary, it is noted that the claimed subject matter are not limited in any way by these various embodiments.

### BRIEF DESCRIPTION OF THE DRAWINGS

The accompanying drawings, which are incorporated in and form a part of this specification and in which like numerals depict like elements, illustrate embodiments of the present disclosure and, together with the detailed description, serve to explain the principles of the disclosure. The drawings are not necessarily to scale.

FIG. 1A is a schematic of different tunnel junction ultraviolet (UV) light emitting diode (LED) device structures in accordance with various embodiments of the present disclosure.

FIG. 1B is a high-angle annular dark-field scanning transmission electron microscopy (HAADF-STEM) image of the complete device structure of Sample A in accordance with various embodiments of the present disclosure.

FIG. 1C is an atomic-scale HAADF-STEM of the tunnel junction region showing crystalline epitaxial growth of p-AlGaN/GaN/n-AlGaN in accordance with various embodiments of the present disclosure.

FIG. 1D is an atomic-resolution HAADF-STEM of the AlGaN quantum well active region in accordance with various embodiments of the present disclosure.

FIG. 2A is a graph of J-V characteristics of the different tunnel junction UV LED device structures in accordance with various embodiments of the present disclosure.

FIG. 2B is a graph of room-temperature electroluminescence spectra measured for the different devices under current injection densities approximately 40 A/cm² in accordance with various embodiments of the present disclosure.

FIG. 2C is a graph of electroluminescence spectra measured at polarization angles of 0° and 90° for sample A (245 nm), shown as straight lines, and an identical device with emission at 265 nm, shown as dashed lines in accordance with various embodiments of the present disclosure.

FIG. 2D is a graph of variation of electroluminescence intensity with polarization angle measured for sample A (245 nm), and an identical device with emission at 265 nm, in accordance with various embodiments of the present disclosure.

FIG. 3A is a graph of EQE vs. current density of Sample A and C, measured using CW bias in accordance with various embodiments of the present disclosure.

FIG. 3B is a graph of WPE vs. current density of Sample A and C, measured using CW bias in accordance with various embodiments of the present disclosure.

FIG. 4A is a structure of the sample used for optical measurements in accordance with various embodiments of the present disclosure.

FIG. 4B is a graph of room-temperature photoluminescence spectra for the structure measured using 193 nm excitation in accordance with various embodiments of the present disclosure.

FIG. 4C is a graph of intensity-dependent photoluminescence spectra measured for the sample using quasi-resonant excitation of the active region in accordance with various embodiments of the present disclosure.

FIG. 4D is a graph of relative EQE measured for optical emission at different excitation powers in accordance with various embodiments of the present disclosure.

FIG. 4E is a graph of variation of peak position with excitation power density in accordance with various embodiments of the present disclosure.

FIG. 4F is a plot of measured full-width half maximum (FWHM) for the emission peak at different excitation power densities in accordance with various embodiments of the present disclosure.

FIG. 5A is a graph of time-resolved photoluminescence decays at different excitation powers collected for the sample used in optical measurements in accordance with various embodiments of the present disclosure.

FIG. 5B is a plot of extracted carrier lifetime vs. excitation power density in accordance with various embodiments of the present disclosure.

FIG. 6 is a flow diagram of a method in accordance with various embodiments of the present disclosure.

### DETAILED DESCRIPTION OF THE INVENTION

Reference will now be made in detail to various embodiments in accordance with the present disclosure, examples of which are illustrated in the accompanying drawings. While described in conjunction with various embodiments, it will be understood that these various embodiments are not intended to limit the present disclosure. On the contrary, the present disclosure is intended to cover alternatives, modifications and equivalents, which may be included within the scope of the present disclosure. Furthermore, in the following detailed description of various embodiments in accordance with the present disclosure, numerous specific details are set forth in order to provide a thorough understanding of the present disclosure. However, it will be evident to one of ordinary skill in the art that the present disclosure may be practiced without these specific details or with equivalents thereof. In other instances, well known methods, procedures, components, and circuits have not been described in detail as not to unnecessarily obscure aspects and features of the present disclosure.

The figures of the present disclosure are not necessarily drawn to scale, and only portions of the devices and structures may be depicted, as well as the various layers that form those structures, are shown. For simplicity of discussion and illustration, only one or two devices or structures may be described, although in actuality more than one or two devices or structures may be present or formed. Also, while certain elements, components, and layers are discussed, embodiments in accordance with the present disclosure are not limited to those elements, components, and layers. For example, there may be other elements, components, layers, and the like in addition to those discussed.

Some portions of the detailed descriptions that follow are presented in terms of procedures and other representations of operations for fabricating devices like those disclosed herein. These descriptions and representations are the means used by those skilled in the art of device fabrication to most effectively convey the substance of their work to others skilled in the art. In the present application, a procedure, operation, or the like, is conceived to be a self-consistent sequence of steps or instructions leading to a desired result. Operations described as separate blocks may be combined and performed in the same process step (that is, in the same time interval, after the preceding process step and before the next process step). Also, the operations may be performed in a different order than the order in which they are described below. Furthermore, fabrication processes and steps may be performed along with the processes and steps discussed herein; that is, there may be a number of process steps before, in between, and/or after the steps shown and described herein. Importantly, embodiments according to the present disclosure can be implemented in conjunction with these other (perhaps conventional) processes and steps without significantly perturbing them. Generally speaking, embodiments according to the present disclosure can replace portions of a conventional process without significantly affecting peripheral processes and steps.

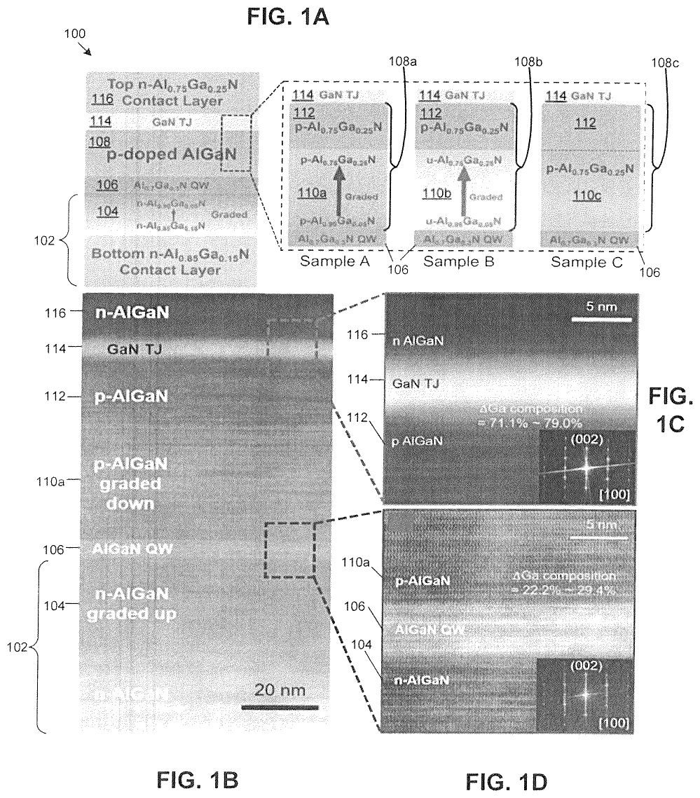

FIG. 1A is a schematic of different tunnel junction ultraviolet (UV) light emitting diode (LED) device structures in accordance with various embodiments of the present disclosure. In various embodiments, aluminum gallium nitride (AlGaN) LED heterostructures (e.g., LED heterostructure 100 with Sample A, LED heterostructure 100 with Sample B, and LED heterostructure 100 with Sample C) were grown on aluminum nitride (AlN)-on-sapphire substrates using a Veeco Gen 930 plasma-assisted molecular beam epitaxy (MBE) system. Note that in various embodiments other types of substrates may be used instead of sapphire substrates such as silicon substrates, but are not limited to such. The epitaxy was performed under slightly Ga-rich conditions at a substrate temperature approximately 750° C. Three different tunnel junction LED designs, Samples A, B, and C, schematically shown in FIG. 1A, were studied. All the structures consist of an initial bottom n-doped AlGaN (n-AlGaN) contact layer 102 with a thickness of 500 nanometer (nm), for example. Preceding the active region 106, the Al composition of the n-AlGaN layer 102 was graded up from approximately 85% to approximately 95% as shown within upper portion 104 of the n-AlGaN layer 102. In addition, the Ga composition of the n-AlGaN layer 102 was graded from approximately 15% to approximately 5% as shown within upper portion 104. In an embodiment, the active region 106 consisted of a single 6 nm thick AlGaN quantum well (QW) 106 emitting at approximately 245 nm. In various embodiments, the use of a single quantum well 106 minimizes the issue of non-uniform carrier injection in the quantum well active region 106. To pinpoint the effect of electron overflow, the design of the p-doped region 108 was varied between Samples A, B, and C. The p-doped region 108a of Sample A included a 25 nm Mg-doped AlGaN electron blocking layer 110a immediately following the active region 106, which was graded from an Al composition approximately 95% to approximately 75%. In addition, the Ga composition of the Mg-doped AlGaN electron blocking layer 110a was also graded from approximately 5% to approximately 25%. Sample B is identical to sample A, except the AlGaN electron blocking layer 110b is undoped, relying solely on polarization-induced doping for generation of charge carriers (holes). Previous studies have shown that the scheme of compositional grading can enhance the effective p-type doping of AlGaN layers. Sample C is identical to sample A except that the compositionally graded AlGaN:Mg electron blocking layer 110c is replaced with a uniform Al_{0.75}Ga_{0.25}N:Mg layer of the same thickness. Following the AlGaN electron blocking layers 110a, 110b, and 110c, a 25 nm thick p-Al_{0.75}Ga_{0.25}N layer 112 was grown for all three samples A, B, and C. Subsequently, a 5 nm thick GaN layer 114 was grown over the p-doped layer 108 (e.g., 108a, 108b, and 108c) followed by an n-doped Al_{0.75}Ga_{0.25}N layer 116, collectively forming the tunnel junction. In various embodiments, the thickness of the n-Al_{0.75}Ga_{0.25}N layer 116 is 150 nm to allow adequate current spreading.

In various embodiments, structural properties of Sample A of FIG. 1A were studied by using a JEOL 3100R05 microscope with Cs aberration corrected STEM (300 keV, 22 mrad) and a ADF detector with 120 mm camera lengths and a detector angle of 59 (inner)—354 mrad (outer). FIG. 1B is a high-angle annular dark-field scanning transmission electron microscopy (HAADF-STEM) image of the complete device structure of Sample A of FIG. 1A in accordance with various embodiments of the present disclosure. Note that the HAADF-STEM image of FIG. 1B confirms the cross-sectional device heterostructure for Sample A. FIG. 1C is an atomic-scale HAADF-STEM of the tunnel junction region showing crystalline epitaxial growth of p-AlGaN 112/GaN 114/n-AlGaN 116 in accordance with various embodiments of the present disclosure. It is noted that atomic-resolution cross-sectional STEM in FIG. 1C reveals the GaN layer 114 (approximately 5 nm) epitaxially grown between the top n⁺-AlGaN 116 and p-AlGaN layer 112. Relative gallium concentration is determined by the HAADF intensity along defined by,

$${I}_{HAADF} = t \cdot [ {( {f}_{Ga} {Z}_{Ga} + {f}_{Al} {Z}_{Al} )}^{γ} + {Z}_{{N}^{γ}} ] ,$$

where/HAADF is the high-angle annular dark field intensity, t is the cross-section thickness, f is the concentration of Ga or Al in the AlGaN multilayers, Z is the atomic number of Al, Ga, or N in the layers, and y is between 1.4 and 1.7. The ratio of HAADF STEM intensity estimates approximately 75.0%±4.0% less Ga in the p-AlGaN layers compared with the Ga concentration in the GaN layer 114. FIG. 1D also shows the epitaxial growth of AlGaN quantum well 106 (approximately 6 nm) with approximately 25.8%+3.6% higher content of Ga relative to adjacent AlGaN barriers in the graded active region. It is noted that FIG. 1D is an atomic-resolution HAADF-STEM of the AlGaN quantum well active region in accordance with various embodiments of the present disclosure. The brighter atomic layers in the active region corresponding to the Ga-rich layers reveals significant compositional non-uniformity in the epilayers due to the use of slight metal-rich epitaxy conditions. Fast Fourier transform (FFT) patterns of the HAADF-STEM images also exhibit ordering of Ga-rich layer along direction, which are forbidden in electron diffraction pattern of wurtzite hexagonal symmetry. In other words, FFT shows the superlattice peak associated with Ga-rich atomic ordering (brighter layers in the corresponding HAADF-STEM image) in wurtzite AlGaN along c-plane direction. The formation of extensive nanoscale AlGaN clusters can provide three-dimensional quantum-confinement of charge carriers, which was shown to dominate the EL of MBE-grown AlGaN UV LEDs and is the principle mechanism for the enhanced internal quantum efficiency for AlGaN grown by PA-MBE.

In various embodiments, for the UV LED fabrication, firstly ion milling was used to etch down to the bottom n-AlGaN layer to make the device mesas. 300 nm of SiO₂ was deposited using PECVD for insulation. Reactive ion etching, with high selectivity between AlGaN and SiO₂, was used to etch vias in the insulation layer for the deposition of metal contacts. A Ti/Al/Ni/Au metal stack was deposited onto the exposed top and bottom n-AlGaN for the device contacts. Annealing of the contacts was performed in a nitrogen ambient at 700° C. for 30 seconds. Al/Au metal contact pads were deposited over the annealed device contacts to facilitate electrical probing and measurements.

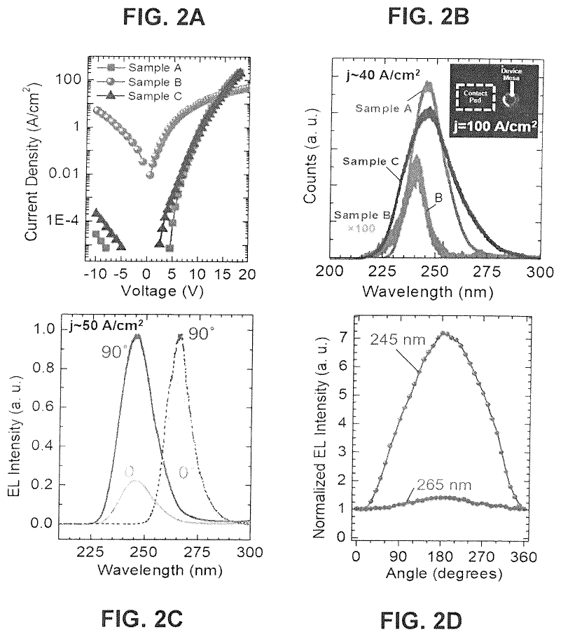

FIG. 2A is a graph of J-V characteristics of the different tunnel junction UV LED device structures of Samples A, B, and C in accordance with various embodiments of the present disclosure. The electrical properties of the devices were measured under continuous-wave (CW) biasing conditions using a Keithley 2400 SMU. The J-V characteristics of representative devices are shown in FIG. 2A. Sample B, which relies solely on polarization doping, is observed to be leaky, while Samples A and C show excellent rectifying characteristics. This indicates that a proper p-n junction was not formed in Sample B. Sample A exhibits a higher turn-on voltage as compared to Sample C; however, the turn-on is significantly sharper for sample A. Severe electron overflow can result in an earlier, but more gradual turn-on voltage for LEDs, indicating that electron overflow is better controlled in sample A, due to the polarization engineered electron blocking layer (e.g., 110a). Samples A and C show very similar characteristics at high forward bias, indicating that they have similar device resistances. The ideality factor calculated for Samples A, B, and C are 7.74, 18.15, and 12.48, respectively. The relatively high ideality factors are a consequence of the presence of a tunnel junction (e.g., 114 and 116) in the devices, as well as the hole transport being dominated by tunneling within an impurity band of AlGaN. However, since all three devices (Samples A, B, and C) have identical tunnel junction design, the significant differences in the measured ideality factors may be a result of other factors. Higher ideality factors have been associated with insufficient doping, higher layer resistances and increased electron overflow. From these measurements it is concluded that the polarization-engineered AlGaN:Mg electron blocking layer in various embodiments plays a crucial role in charge carrier transport, and its presence is beneficial to improved current-voltage characteristics.

FIG. 2B is a graph of room-temperature electroluminescence (EL) spectra measured for the different devices (Samples A, B, and C) under similar current injection densities approximately 40 A/cm² in accordance with various embodiments of the present disclosure. Note that the electroluminescence of sample B has been magnified by a factor of 100. The peak of the EL spectrum is measured at approximately 245 nm for all the samples. Samples A and C exhibit relatively bright luminescence, however the luminescence from Sample B is significantly weaker. The full-width half maximum (FWHM) is measured to be approximately 15 nm for sample A, which is comparable to previously reported LEDs grown by MBE. Sample B has a similar FWHM, although it also exhibits a shoulder at shorter wavelengths close to 235 nm, suggesting that there is significant recombination of charge carriers within the higher Al content layers of the device. Sample C has a significantly broader emission peak with FWHM over 25 nm. The wide emission peak is a strong indication of more severe electron overflow in this device. Further, Sample C also shows a relatively long tail as compared to the other devices, which can be explained by emission from the Mg acceptor related transition of the p-doped Al_{0.75}Ga_{0.25}N. In accordance with an embodiment, the inset of FIG. 2B shows a device from Sample A under an injection current of 100 A/cm². It is seen that there is a significant amount of light being emitted from the edges of the device mesa, despite the metal contact completely covering the top of the device.

The emission polarization properties of sample A was studied as well as an LED with an identical structure but having emission at 265 nm. The samples were placed under a constant CW bias corresponding to an injected current density approximately 50 A/cm². A Glan-Taylor calcite polarizer with a high-precision rotation mount system was placed on the sample top surface to resolve the emission. FIG. 2C is a graph of electroluminescence (EL) spectra measured at polarization angles of 0° and 90° for sample A (245 nm), shown as straight (solid) lines, and an identical device with emission at 265 nm, shown as dashed lines in accordance with various embodiments of the present disclosure. In other words, FIG. 2C plots the EL spectra for the two devices at polarization angles of 0° and 90°. A much larger change in intensity was seen for the Sample A 245 nm LED as compared to the 265 nm device, suggesting a significantly larger degree of polarization. This is consistent with previous studies that reported the light emission becoming more TM polarized for higher Al compositions. The variation of the EL intensity, normalized to the minimum value for each device, with polarization angle for the two devices is shown in FIG. 2D. In other words, FIG. 2D is a graph of variation of electroluminescence intensity with polarization angle measured for sample A (245 nm) in light gray, and an identical device with emission at 265 nm in dark grey, in accordance with various embodiments of the present disclosure. The degree of polarization was measured to be −0.602 and −0.078 for the 245 nm and 265 nm LEDs, respectively, which confirms a major shift towards emission that is dominantly TM-polarized with decreasing wavelengths. It is therefore expected that the device efficiency can be significantly enhanced by engineering the polarization of the light emission to be more TE-like, by utilizing nanostructures, and/or by removing the substrate.

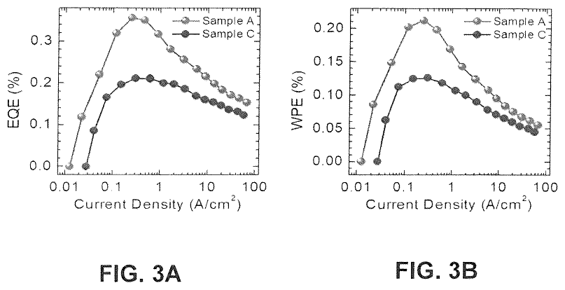

FIG. 3A is a graph of EQE vs. current density of Sample A and C, measured using CW bias in accordance with various embodiments of the present disclosure. FIG. 3B is a graph of WPE vs. current density of Sample A and C, measured using CW bias in accordance with various embodiments of the present disclosure. Note that FIGS. 3A and 3B show the variation of EQE and WPE, respectively, with current density for samples A and C. It is noted that the output power was measured from the bottom of the sapphire substrate using a Newport 818-ST2-UV photodetector with a Newport Model 1919-R power meter. The devices were probed under CW biasing conditions. The maximum EQE and WPE for sample A are 0.35% and 0.21%, respectively, at a current density of 0.25 A/cm². The peak EQE and WPE of sample A is over 50% higher than that of sample C. In fact, the measured efficiency values are more than one order of magnitude higher than previously reported tunnel junction devices at these wavelengths. Sample B exhibited extremely low efficiency (approximately 0.001%), due to the leaky I-V, which is not shown here. Given that both samples A and C have identical active region and tunnel junction designs, the improved performance of sample A can be well explained by the incorporation of a polarization engineered p-AlGaN electron blocking layer (EBL) layer 110a, which can help reduce electron overflow and enhance the device efficiency. This observation is also consistent with the enhanced electron overflow of sample C derived from electrical analysis, as described above. The underlying cause for the severe electron overflow is due to the highly asymmetric electron and hole transport properties of Al-rich AlGaN, which fundamentally limits the maximum achievable efficiency of deep UV LEDs.

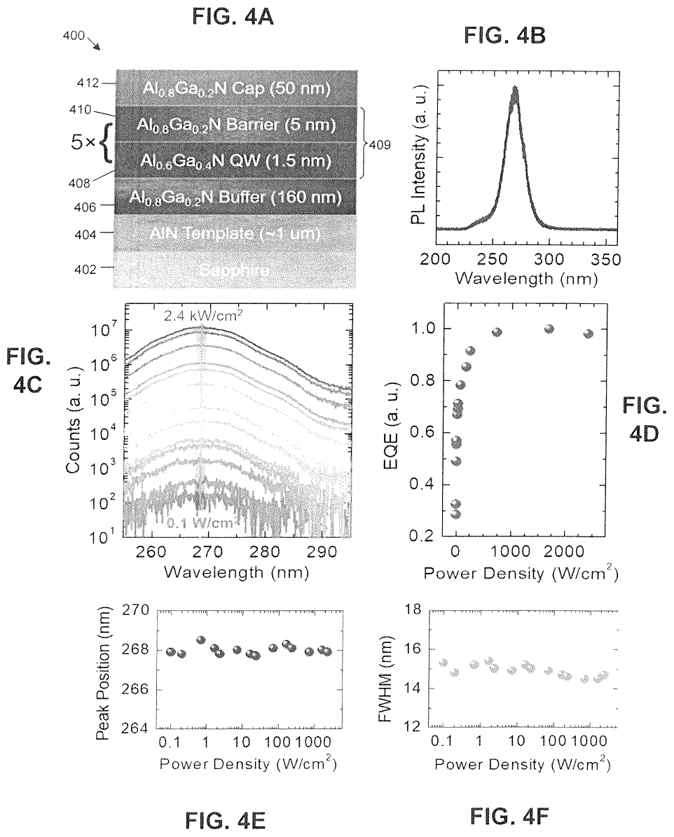

It is also noticed that similar efficiency droop phenomena have been measured in AlGaN LEDs operating at 255-280 nm wavelengths. To further confirm if the observed efficiency droop is due to an electrical effect, the optical properties were studied of the AlGaN quantum well active region (approximately 265 nm), schematically shown in FIG. 4A, to determine if it plays a significant role in the efficiency droop process. FIG. 4A is a structure 400 of the sample used for optical measurements in accordance with various embodiments of the present disclosure. Within the present embodiment of FIG. 4A, note that structure 400 can include, but is not limited to, a sapphire substrate 402 upon which an AlN template 404 is formed have a thickness of approximately 1 micrometer (um). In addition, the structure 400 can include an approximately 160 nm thick Al_{0.8}Ga_{0.2}N buffer layer 406 formed on the AlN template 404. The structure 400 also can include a 1.5 nm thick Al_{0.6}Ga_{0.4}N quantum well (QW) layer 408 formed on the Al_{0.8}Ga_{0.2}N buffer layer 406 and a 5 nm thick Al_{0.8}Ga_{0.2}N barrier layer 410 formed on the Al_{0.6}Ga_{0.4}N quantum well layer 408. It is noted that structure 400 can include an active region 409 that can include five stacks of the Al_{0.6}Ga_{0.4}N quantum well layer 408 and the Al_{0.8}Ga_{0.2}N barrier layer 410. Furthermore, the structure 400 can also include a 50 nm thick Al_{0.8}Ga_{0.2}N cap layer 412 formed on the active region 409. FIG. 4B is a graph of room-temperature photoluminescence (PL) spectra for the structure 400 measured using 193 nm excitation in accordance with various embodiments of the present disclosure. In other words, FIG. 4B shows the PL spectrum measured by exciting the sample 400 using a 193 nm Coherent Excistar XS500 laser. It shows the presence of two peaks, one located at approximately 240 nm originating from the high Al-content barrier layers 410, and another at approximately 268 nm, originating from the quantum wells 408. To study only the luminescence from the quantum wells 408, and avoid the effects of carrier transport between the wells 408 and barriers 410, the sample 400 was resonantly excited using a frequency-tripled Ti:sapphire laser (approximately 245 nm) with an 80 MHz repetition rate and 100 fs pulse width. The excitation power was varied over several orders of magnitude and the PL spectra are shown in FIG. 4C. It is noted that FIG. 4C is a graph of intensity-dependent photoluminescence spectra measured for the sample 400 using quasi-resonant excitation of the active region 409 in accordance with various embodiments of the present disclosure. FIG. 4D is a graph of relative EQE measured for optical emission at different excitation powers in accordance with various embodiments of the present disclosure. The relative EQE is shown in FIG. 4D, exhibiting no significant droop up to an excitation power of 2.4 kW/cm², which corresponds to an estimated carrier density approximately 2×10¹⁸ cm⁻³. A negligible change in peak position was seen over this wide excitation range, shown in FIG. 4E, suggesting that the emission is a result of the radiative recombination of highly confined and localized carriers. Note that FIG. 4E is a graph of variation of peak position with excitation power density in accordance with various embodiments of the present disclosure. The linewidth of the emission, plotted against excitation power in FIG. 4F, remains almost constant throughout the excitation range, showing negligible quantum-confined Stark effect. It is noted that FIG. 4F is a plot of measured full-width half maximum (FWHM) for the emission peak at different excitation power densities in accordance with various embodiments of the present disclosure.

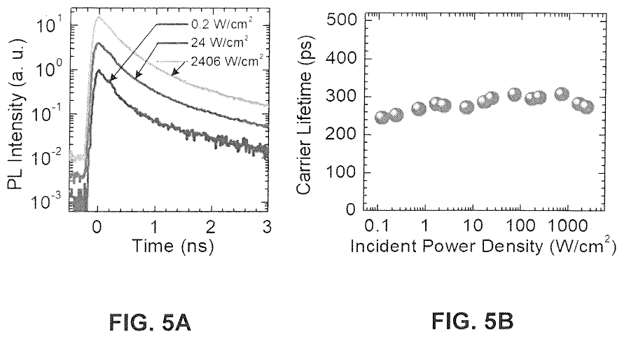

FIG. 5A is a graph of time-resolved photoluminescence decays at different excitation powers collected for the sample 400 used in optical measurements in accordance with various embodiments of the present disclosure. Note that TRPL transients were also collected at different optical excitation powers using a thermoelectrically cooled fast hybrid photomultiplier tube. Some representative transients are shown in FIG. 5A, which exhibit an almost negligible change in their decay over the excitation range. FIG. 5B is a plot of extracted carrier lifetime vs. excitation power density in accordance with various embodiments of the present disclosure. Note that FIG. 5B plots the extracted carrier lifetimes by using the stretched-exponential model. The nearly invariant carrier lifetime (approximately 0.3 ns) shows that the carrier recombination dynamics do not change significantly over the excitation range, suggesting that higher order carrier loss processes, e.g., Auger recombination, is not significant in the measured excitation power range. Auger recombination would cause an increase in non-radiative emission and a decrease in carrier lifetime when the excitation power is increased. The carrier lifetimes measured were comparable to previously reported high quality AlGaN epilayers grown by MBE. It is also noteworthy that the extracted carrier lifetimes are significantly lower than those measured for AlGaN quantum wells grown by metal-organic chemical vapor deposition (MOCVD), which can be explained by the strong quantum-confinement of charge carriers in the quantum dot-like nanoclusters for samples grown by plasma-assisted MBE. In addition, recent studies have shown that the exciton binding energy can be significantly enhanced in AlGaN nanostructures, which also contribute to the reduced radiative lifetime. Furthermore, no evidence of droop is observed in the optical measurements up to an estimated carrier density approximately 2×10¹⁸ cm³. For comparison, previously reported blue-emitting InGaN quantum wells also did not display any efficiency droop up to carrier densities approximately 5×10¹⁸ cm⁻³, which approximately corresponds to injection current densities 5-15 A/cm². Given the shorter carrier lifetime measured in the presented AlGaN active region, the carrier density approximately 2×10¹⁸ cm⁻³ would correspond to a higher current density than that observed in InGaN LEDs for the onset of efficiency droop. Therefore, it is reasonable to conclude the measured efficiency droop in electroluminescence at approximately 0.25 A/cm² is not an optical phenomenon, but instead related to an electrical origin, e.g., electron overflow.

In various embodiments, AlGaN deep UV tunnel junction LEDs have been demonstrated operating at approximately 245 nm, which exhibit significantly improved efficiency compared to previous reports. Severe efficiency droop was measured at low current densities. Detailed electrical and optical studies suggest that the efficiency droop is directly related to electron overflow, instead of an optical phenomenon. Moreover, the MBE grown AlGaN deep UV LED active region is characterized with the presence of nanoscale clusters. The resulting strong three-dimensional confinement of charge carriers can significantly reduce quantum-confined Stark effect, leading to highly stable and efficient emission. Studies based on various embodiments further suggest that AlGaN deep UV LEDs with efficiency comparable to InGaN blue-emitting quantum wells can be potentially achieved, if issues related to electron overflow and TM polarized emission are effectively addressed.

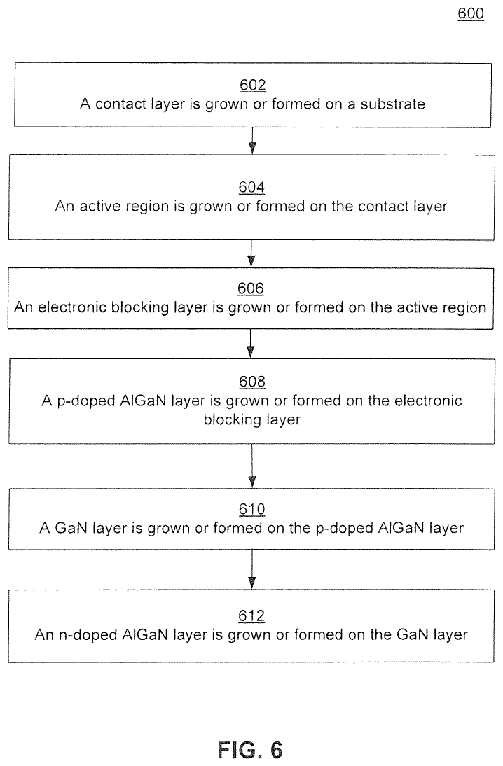

FIG. 6 is a flow diagram of a method 600 for fabricating tunnel junction ultraviolet (UV) light emitting diode (LED) device structures (e.g., 100) in accordance with various embodiments of the present disclosure.

At 602, a contact layer (e.g., 102) is grown or formed on a substrate. Note that 602 can be implemented in a wide variety of ways. For example, in various embodiments, an upper portion (e.g., 104) of the contact layer at 602 can be composition graded. It is noted that 602 can be implemented in any manner similar to that described and/or shown by the present disclosure, but is not limited to such.

At 604 of FIG. 6, an active region (e.g., 106) is grown or formed on the contact layer (e.g., 102). It is noted that 604 can be implemented in a wide variety of ways. For example, in various embodiments, the active region at 604 can include a single quantum well (e.g., 106). Note that 604 can be implemented in any manner similar to that described and/or shown by the present disclosure, but is not limited to such.

At 606, an electronic blocking layer (e.g., 110a, 110b, or 110c) is grown or formed on the active region (e.g., 106). Note that 606 can be implemented in a wide variety of ways. For example, the electronic blocking layer (e.g., 110a, 110b, or 110c) at 606 can be implemented in any manner similar to that described and/or shown by the present disclosure, but is not limited to such.

At 608 of FIG. 6, a p-doped AlGaN layer (e.g., 112) is grown or formed on the electronic blocking layer (e.g., 110a, 110b, or 110c). It is noted that 608 can be implemented in a wide variety of ways. For example, the p-doped AlGaN layer (e.g., 112) at 608 can be implemented in any manner similar to that described and/or shown by the present disclosure, but is not limited to such.

At 610, a GaN layer (e.g., 114) is grown or formed on the p-doped AlGaN layer (e.g., 112). Note that 610 can be implemented in a wide variety of ways. For example, the GaN layer (e.g., 114) at 610 can be implemented in any manner similar to that described and/or shown by the present disclosure, but is not limited to such.

At 612 of FIG. 6, an n-doped AlGaN layer (e.g., 116) is grown or formed on the GaN layer (e.g., 114). It is noted that 612 can be implemented in a wide variety of ways. For example, the n-doped AlGaN layer (e.g., 116) at 612 can be implemented in any manner similar to that described and/or shown by the present disclosure, but is not limited to such. In various embodiments, note that the GaN layer (e.g., 114) at 610 and the n-doped AlGaN layer (e.g., 116) at 612 collectively form the tunnel junction of the UV LED (e.g., 100).

Therefore, FIG. 6 is a flow diagram of the method 600 for fabricating tunnel junction ultraviolet (UV) light emitting diode (LED) device structures (e.g., 100) in accordance with various embodiments of the present disclosure.

Note that the following are examples in accordance with various embodiments of the present disclosure.

Example 1. A light emitting diode (LED) including:
a composition graded electron blocking layer;
wherein the LED is operable for emitting light.

Example 2. The LED of Example 1, wherein the composition graded electron blocking layer includes aluminum gallium nitride (AlGaN).

Example 3. The LED of Example 1, wherein the composition graded electron blocking layer includes magnesium (Mg) doping.

Example 4. The LED of Example 1, wherein the composition graded electron blocking layer includes Mg doped AlGaN.

Example 5. The LED of Example 1 or 2 or 3 or 4, wherein the composition graded electron blocking layer includes an aluminum (Al) composition graded from approximately 95% to approximately 75%.

Example 6. The LED of Example 1, wherein the composition graded electron blocking layer is polarization engineered.

Example 7. The LED of Example 1 or 5 or 6, wherein the light includes a peak in the electroluminescence (EL) spectrum less than 250 nanometers (nm).

Example 8. The LED of Example 7, wherein the LED includes an external quantum efficiency (EQE) of at least 0.3% at a current density of at least 0.25 A/cm².

Example 9. The LED of Example 7 or 8, wherein the LED includes a wall-plug efficiency (WPE) of at least 0.2% at a current density of at least 0.25 A/cm².

Example 10. The LED of Example 7, wherein the LED includes a nearly invariant carrier lifetime over an excitation range of 0.1 to 3000 W/cm².

Example 11. A light emitting diode (LED) heterostructure, including:
a quantum well layer;
an electron blocking layer; and
a tunnel junction;
wherein the LED heterostructure is operable for emitting light.

Example 12. The LED heterostructure of Example 11, wherein the electron blocking layer includes composition grading.

Example 13. The LED heterostructure of Example 11, wherein the electron blocking layer includes aluminum gallium nitride (AlGaN).

Example 14. The LED heterostructure of Example 11, wherein the electron blocking layer includes magnesium (Mg) doping.

Example 15. The LED heterostructure of Example 11, wherein the electron blocking layer includes Mg doped AlGaN.

Example 16. The LED heterostructure of Example 11 or 12 or 13 or 14 or 15, wherein the electron blocking layer includes an aluminum (Al) composition graded from approximately 95% to approximately 75%.

Example 17. The LED heterostructure of Example 11 or 12 or 13 or 14 or 15 or 16, wherein the light includes a peak in the electroluminescence (EL) spectrum less than 250 nanometers (nm).

Example 18. The LED heterostructure of Example 11 or 12 or 13 or 14 or 15 or 16 or 17, wherein the tunnel junction includes a gallium nitride (GaN) layer.

Example 19. A light emitting diode (LED) including:
a electron blocking layer; and
a tunnel junction layer;
wherein the LED is operable for emitting light at a peak in the electroluminescence (EL) spectrum less than 250 nm.

Example 20. The LED of Example 19, wherein the light includes a peak in the EL spectrum in a wavelength range of approximately 210-259 nm.

Example 21. The LED of Example 19 or 20, wherein the electron blocking layer includes magnesium (Mg) doping.

Example 22. The LED of Example 19 or 20 or 21, wherein the electron blocking layer includes composition grading.

Example 23. The LED of Example 19 or 20 or 21 or 22, wherein the electron blocking layer is polarization engineered.

Example 24. The LED of Example 19 or 20 or 21 or 22 or 23, wherein the electron blocking layer includes AlGaN.

Example 25. The LED of Example 19 or 20 or 21 or 22 or 23 or 24, wherein the LED includes an external quantum efficiency (EQE) of at least 0.3% at a current density of at least 0.25 A/cm².

Example 26. The LED of Example 19 or 20 or 21 or 22 or 23 or 24 or 25, wherein the LED includes a wall-plug efficiency (WPE) of at least 0.2% at a current density of at least 0.25 A/cm².

Example 27. The LED of Example 19 or 20 or 21 or 22 or 23 or 24 or 25 or 26, wherein the tunnel junction layer includes gallium nitride (GaN).

Example 28. The LED of Example 19 or 20 or 21 or 22 or 23 or 24 or 25 or 26 or 27, wherein the tunnel junction layer includes AlGaN.

Example 29. The LED heterostructure of Example 11 or 12 or 13 or 14 or 15 or 16 or 17 or 18, wherein the tunnel junction includes an AlGaN layer.

Example 30. The LED heterostructure of Example 11 or 12 or 13 or 14 or 15 or 16 or 17 or 18, wherein the tunnel junction includes an n-doped AlGaN layer.

Example 31. The LED heterostructure of Example 11 or 12 or 13 or 14 or 15 or 16 or 17 or 18, wherein the tunnel junction includes an n-doped Al_{0.75}Ga_{0.25}N layer.

Example 32. The LED heterostructure of Example 11 or 12 or 13 or 14 or 15 or 16 or 17 or 18, wherein the quantum well layer is a single quantum well layer.

Example 33. The LED of Example 1 or 2 or 3 or 4 or 5 or 6 or 7 or 8 or 9, further including a quantum well.

Example 34. The LED of Example 33, wherein the quantum well is a single quantum well.

Although various subject matter of the present disclosure has been described in language specific to structural features and/or methodological acts, it is to be understood that the various subject matter defined in the present disclosure is not necessarily limited to the specific features or acts described herein. Rather, the specific features and acts described herein are disclosed as various example forms of implementing the present disclosure.

Various embodiments of the present disclosure are thus described. While the present disclosure has been described in particular embodiments, it should be appreciated that the present disclosure should not be construed as limited by such embodiments, but rather construed according to the following claims.

What is claimed is:

1. A light emitting diode (LED) comprising:
a composition graded electron blocking layer;
wherein the LED is operable for emitting light.

2. The LED of claim 1, wherein the composition graded electron blocking layer comprises aluminum gallium nitride (AlGaN).

3. The LED of claim 1, wherein the composition graded electron blocking layer comprises magnesium (Mg) doping.

4. The LED of claim 1, wherein the composition graded electron blocking layer comprises Mg doped AlGaN.

5. The LED of claim 1, wherein the composition graded electron blocking layer comprises an aluminum (Al) composition graded from approximately 95% to approximately 75%.

6. ED of claim 1, wherein the composition graded electron blocking layer is polarization engineered.

7. The LED of claim 1, wherein the light comprises a peak in the electroluminescence (EL) spectrum less than 250 nanometers (nm).

8. The LED of claim 7, wherein the LED comprises an external quantum efficiency (EQE) of at least 0.3% at a current density of at least 0.25 A/cm².

9. The LED of claim 7, wherein the LED comprises a wall-plug efficiency (WPE) of at least 0.2% at a current density of at least 0.25 A/cm².

10. The LED of claim 7, wherein the LED comprises a nearly invariant carrier lifetime over an excitation range of 0.1 to 3000 W/cm².

11. A light emitting diode (LED) heterostructure, comprising:
a quantum well layer;
an electron blocking layer; and
a tunnel junction;
wherein the LED heterostructure is operable for emitting light.

12. The LED heterostructure of claim 11, wherein the electron blocking layer comprises composition grading.

13. The LED heterostructure of claim 11, wherein the electron blocking layer comprises aluminum gallium nitride (AlGaN).

14. The LED heterostructure of claim 11, wherein the electron blocking layer comprises magnesium (Mg) doping.

15. The LED heterostructure of claim 11, wherein the electron blocking layer comprises Mg doped AlGaN.

16. The LED heterostructure of claim 11, wherein the electron blocking layer comprises an aluminum (Al) composition graded from approximately 95% to approximately 75%.

17. The LED heterostructure of claim 11, wherein the light comprises a peak in the electroluminescence (EL) spectrum less than 250 nanometers (nm).

18. The LED heterostructure of claim 11, wherein the tunnel junction comprises a gallium nitride (GaN) layer.

19. A light emitting diode (LED) comprising:
an electron blocking layer; and
a tunnel junction layer;
wherein the LED is operable for emitting light at a peak in the electroluminescence (EL) spectrum less than 250 nm.

20. ED of claim 19, wherein the light comprises a peak in the EL spectrum in a wavelength range of approximately 210-259 nm.

21. The LED of claim 19, wherein the electron blocking layer comprises magnesium (Mg) doping.

22. The LED of claim 19, wherein the electron blocking layer comprises composition grading.

23. The LED of claim 19, wherein the electron blocking layer is polarization engineered.

24. The LED of claim 19, wherein the electron blocking layer comprises AlGaN.

25. The LED of claim 19, wherein the LED comprises an external quantum efficiency (EQE) of at least 0.3% at a current density of at least 0.25 A/cm².

26. ED of claim 19, wherein the LED comprises a wall-plug efficiency (WPE) of at least 0.2% at a current density of at least 0.25 A/cm².
